(19) United States
(12) Patent Application Publication
(10) Pub. No.: US 2013/0135955 A1
(43) Pub. Date: May 30, 2013

(54) MEMORY DEVICE INCLUDING A RETENTION VOLTAGE RESISTOR

(71) Applicants: Edward M. McCombs, Austin, TX (US); Kenneth W. Jones, Austin, TX (US)

(72) Inventors: Edward M. McCombs, Austin, TX (US); Kenneth W. Jones, Austin, TX (US)

(21) Appl. No.: 13/305,796

(22) Filed: Nov. 29, 2011

(51) Int. Cl. G11C 5/14

(52) U.S. Cl. 365/226

(57) ABSTRACT

A mechanism for providing retention mode voltage to a memory storage array includes a resistor coupled between a power supply and a power rail of the storage array. The power rail may distribute an operating current to the bit cells of the storage array. The resistor may provide a path for current to the power rail from the power supply during operation in a retention mode. In addition, a switching device coupled between the power supply and the power rail, in parallel with the resistor, may convey operational current to the power rail from the power supply during operation in a normal mode.

### BACKGROUND

1. Technical Field

This disclosure relates to memories, and more particularly to retention mode voltage mechanisms.

2. Description of the Related Art

Many memory arrays suffer from the effects of current leakage. Typically, the array bit cells are the largest contributor to leakage. This may be attributed to the transistors that are connected in a cross-coupled inverter configuration in each of the many bit cells of an array. Typically the p-type transistors of each bit cell, when they are turned off, may leak to circuit ground through the conducting n-type transistor. One conventional way to reduce the leakage current of a given memory array is to lower the supply voltage to the array when the memory is not being used or when the device is in a low power or standby mode, for example.

However, conventional techniques for supplying the voltage to the array have drawbacks. For example, one such conventional circuit is shown in FIG. 1A. In FIG. 1A, a memory circuit 10 is shown in which an n-type transistor T1 is used to provide the retention mode supply voltage from the top level Vdd to the memory storage array 12, while the p-type transistor T2 provides the normal mode supply voltage from the top level Vdd to the memory storage array 12. Thus, during a normal mode, transistor T2 is conducting, and transistor T1 is cut off. It is well known that p-type transistors are generally better suited to pass a higher voltage since there is no threshold voltage (V_{T}) drop from source to drain when the transistor is conducting. It is further well known that n-type transistors are better suited to providing a path to ground because there is a source to drain V_{T} voltage drop, which can be relatively large. Thus, during a low power or retention mode, transistor T2 is cut off, and transistor T1 is conducting. The retention voltage applied to the storage array 12 is Top Level Vdd−V_{T}. This lower retention Vdd may reduce the leakage in the storage array 12. If the retention voltage is much larger than V_{T}, then this technique may work very well. However, many modern devices may have operating voltages that are close to the V_{T} of the transistor T1. Accordingly, as operating voltages, and thus the top level Vdd gets lower, the retention Vdd available to the storage array 12 may become too low for reliable operation using this technique.

Another conventional circuit uses a p-type transistor to provide the top-level supply voltage to the storage array and is shown in FIG. 1B. In FIG. 1B, a memory circuit 20 is shown in which the top level Vdd is coupled to the storage array 12 through a p-type transistor T3 and a second p-type transistor T4 (which is typically bigger than T3).

As mentioned above, P-type transistors are generally better suited to pass a higher voltage since there is no V_{T} drop from source to drain when the transistor is conducting. Accordingly, during operation in a normal mode a gate voltage (e.g., zero volts) is provided to cause the transistor T3 to operate in saturation. However, to obtain a voltage drop suitable for operation in retention mode, the gate voltage applied to transistor T3 is adjusted to some voltage that is between zero and Vdd, for example, so that transistor T3 operates in the linear region. In this mode, there is a source to drain voltage drop across transistor T3, which effectively lowers the voltage available at the storage array 12. However, due to process and other variations, the gate voltage necessary to operate the transistor T3 at the appropriate operating point can be difficult to obtain consistently. In many cases there is active control circuitry that monitors and maintains the retention voltage at the appropriate levels. This circuitry takes up valuable die space and uses power. In addition, in both FIG. 1A and FIG. 1B, the retention transistors T1 and T3 require additional control wiring that must be routed.

### SUMMARY OF THE EMBODIMENTS

Various embodiments of a memory including a retention mode resistor are disclosed. Broadly speaking, a mechanism for providing retention mode voltage to a memory storage array is contemplated. Since storage arrays may have a large leakage current, it may be beneficial to reduce the voltage to the storage array when it is not in use. Thus during a low power mode, the voltage of the voltage supply coupled to the storage array is reduced to a retention voltage. To provide the retention voltage, a resistor is coupled between the power supply an the storage array power rail in a pull up configuration. During normal operation a switching device may be shunted across the resistor to provide operation current to the storage array.

In one embodiment, a memory includes a storage array including a number of bit cells and a power rail configured to distribute an operating current to the bit cells. The memory also includes a resistor coupled between a power supply and the power rail. The resistor may provide a path for current to the power rail from the power supply during operation in a retention mode. In addition, a switching device such as a p-type transistor, for example, coupled between the power supply and the power rail may convey operational current to the power rail from the power supply during operation in a normal mode.

In one specific implementation, the resistor may be a semiconductor material such as polycrystalline silicon, for example, formed in the semiconductor substrate in which the storage array is formed.

### BRIEF DESCRIPTION OF THE DRAWINGS

FIG. 1A is a block diagram of a memory including a prior art technique for providing retention voltage to a memory array.

FIG. 1B is a block diagram of a memory including another prior art technique for providing retention voltage to a memory array.

FIG. 2 is a block diagram of one embodiment of a memory including a circuit for providing retention voltage to a memory array.

FIG. 3 is a block diagram of one embodiment of a system.

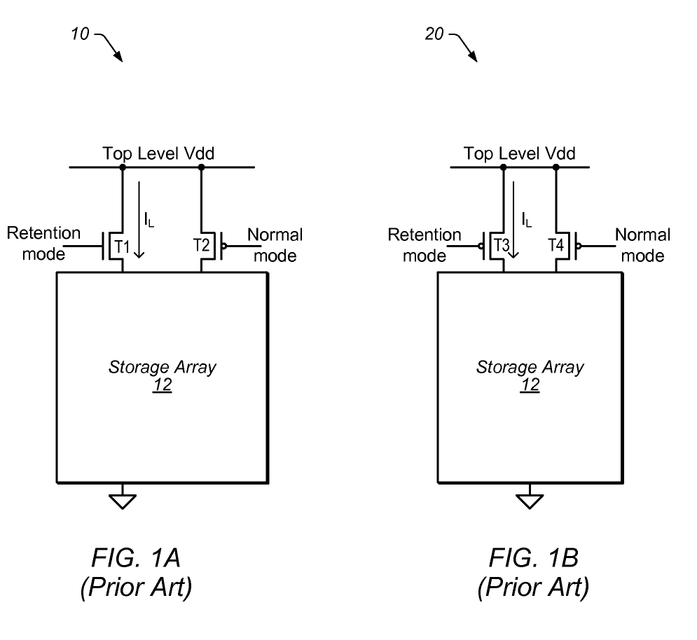

Specific embodiments are shown by way of example in the drawings and will herein be described in detail. It should be understood, however, that the drawings and detailed description are not intended to limit the claims to the particular embodiments disclosed, even where only a single embodiment is described with respect to a particular feature. On the contrary, the intention is to cover all modifications, equivalents and alternatives that would be apparent to a person skilled in the art having the benefit of this disclosure. Examples of features provided in the disclosure are intended to be illustrative rather than restrictive unless stated otherwise.

As used throughout this application, the word “may” is used in a permissive sense (i.e., meaning having the potential to), rather than the mandatory sense (i.e., meaning must). Similarly, the words “include,” “including,” and “includes” mean including, but not limited to.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. §112, paragraph six, interpretation for that unit/circuit/component.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

### DETAILED DESCRIPTION

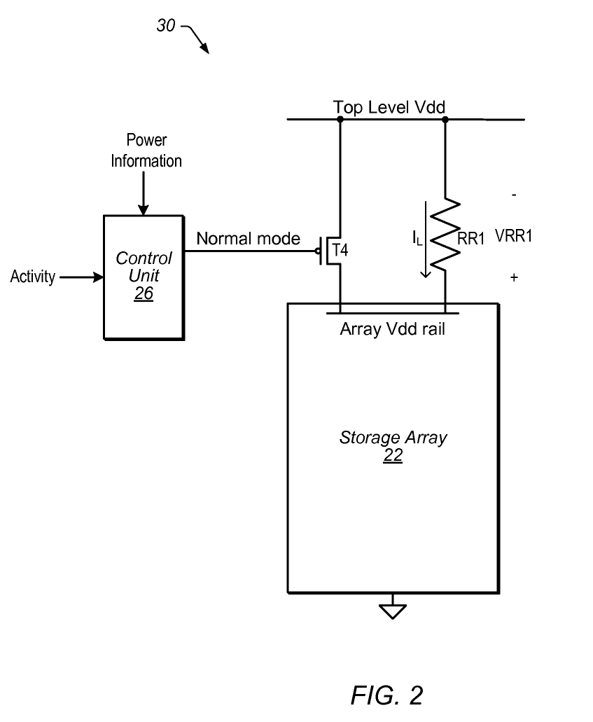

Turning now to FIG. 2, a block diagram of one embodiment of a memory including a circuit for providing retention voltage to a memory array is shown. The memory 30 includes a storage array 22 that is coupled to a circuit ground and to a top level Vdd through a p-type transistor T4, and a retention resistor RR1.

In one embodiment, during operation in a normal mode, a normal mode signal (e.g., zero volts) is applied to the gate of transistor T4 causing it to conduct, thereby providing the top level Vdd to the storage array 12. During operation in the normal mode, because series resistance of the transistor T4 is small compared to the retention resistor RR1, a majority of the operational current will flow through transistor T4 into the storage array 22.

During operation in a low power or retention mode, in one embodiment the normal mode signal may transition to a high logic level, causing transistor T4 to turn off. Accordingly, rather than current flowing through transistor T4, current instead will flow through the retention resistor RR1 into the storage array. In the retention mode, there are no active wordline signals (not shown), and the memory device is inactive. Thus, the current through the resistor RR1 is relatively constant at a given process, voltage, and temperature (PVT), and is due to leakage current I_{L}.

The current through resistor RR1 causes a voltage drop (VRR1) across resistor RR1. Thus the retention voltage available at the storage array 12 may be expressed as top-level Vdd−VRR1. Because the leakage current is relatively constant irrespective of the resistance of RR1, the resistance value of RR1 may be calculated based upon the desired retention voltage and the substantially constant leakage current using Ohm's law. Thus, the resistor RR1 may be manufactured with a resistance value tolerance according to the manufacturing variability and still provide the appropriate retention voltage to the storage array Vdd rail. The value of the resistor RR1 may be designed at a worst-case process voltage and temperature. As such, the actual value of the resistor RR1 at a given PVT may vary, but the variation will thus be accounted for. Having such a tolerance aids in manufacturability.

In one embodiment, since the leakage current I_{L} may be known for the storage array 22, the resistance value of RR1 may be calculated using Ohm's law, in which R=V/I. In this case, R corresponds to the resistance of RR1, V corresponds to the voltage drop VRR1 across the resistor, and the current I is I_{L}. The voltage VRR1 may be determined based upon the worst-case retention voltage supplied to the array Vdd rail. For example, if the top level Vdd is 2.0V, and the worst-case retention voltage is 0.8V, then VRR1 would be 1.2V. Assuming the leakage current I_{L} is 20 μA for the storage array 22, then using Ohm's law, the resistance value of RR1 would be 60KΩ. However, to accommodate manufacturing variances, the voltage of VRR1 could be decreased to provide a resistance range. Accordingly, in this example, the voltage VRR1 could be decreased by some predetermined amount or percentage to allow for whatever variance is expected in the manufacturing process. More particularly, if the manufacturing variance is 10%, the VRR1 could be decreased by 10% to 1.08V. Using Ohm's law, the resulting resistance would be 54KΩ. Accordingly, to keep the retention voltage above the minimum of 0.8V, the resistance may vary between 54KΩ and 60KΩ. It is noted that the above values are merely exemplary and for discussion purposes only.

In one embodiment, the memory device 30, and thus the storage array 22 corresponds to an integrated circuit manufactured on a semiconductor substrate. Accordingly, resistor RR1 may be formed using any of a variety manufacturing techniques that are used to form and trim such resistors. In various embodiments, the resistor RR1 may be implemented using polycrystalline silicon, metal, or combinations thereof, as desired.

As described above in conjunction with the embodiment shown in FIG. 2, providing the retention mode voltage to the storage array power rail through a resistor may allow for manufacturing variability and no additional monitor and control logic. In addition, since the resistor RR1, does not have any gate control signals there are fewer wires to route than in conventional techniques.

It is noted that the memory 30 shown in the embodiment of FIG. 2, may be representative of any type of memory device that may be placed into a retention mode. In one embodiment, the memory device 30 may be implemented as an embedded memory such as a cache memory or a register file within any of a variety of devices such as a processor for example.

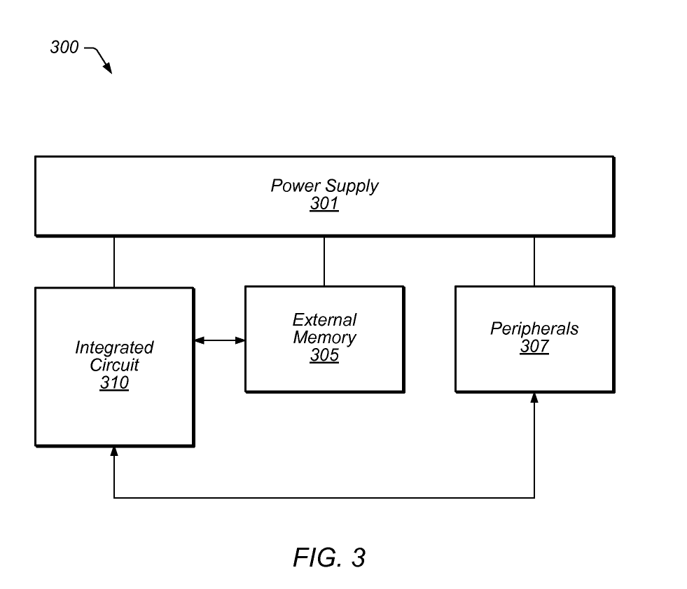

Turning to FIG. 3, a block diagram of one embodiment of a system is shown. The system 300 includes at least one instance of an integrated circuit 310 coupled to one or more peripherals 307 and an external system memory 305. The system 300 also includes a power supply 301 that may provide one or more supply voltages to the integrated circuit 310 as well as one or more supply voltages to the memory 305 and/or the peripherals 307.

In one embodiment, the integrated circuit 310 be a system on a chip (SOC) including one or more instances of a processor and various other circuitry such as a memory controller, video and/or audio processing circuitry, on-chip peripherals and/or peripheral interfaces to couple to off-chip peripherals, etc. Accordingly, the integrated circuit 310 may include one or more instances of an embedded memory such as memory 30 of FIG. 2. Thus, embodiments that include the memory 30 may also include the retention mode resistor described above in conjunction with the description of FIG. 2.

The peripherals 307 may include any desired circuitry, depending on the type of system. For example, in one embodiment, the system 300 may be included in a mobile device (e.g., personal digital assistant (PDA), smart phone, etc.) and the peripherals 307 may include devices for various types of wireless communication, such as WiFi, Bluetooth, cellular, global positioning system, etc. The peripherals 307 may also include additional storage, including various types of RAM storage, solid-state storage, or disk storage. As such, the peripherals 307 may also include RAM that includes the retention mode resistor described above. The peripherals 307 may include user interface devices such as a display screen, including touch display screens or multitouch display screens, keyboard or other input devices, microphones, speakers, etc. In other embodiments, the system 300 may be included in any type of computing system (e.g. desktop personal computer, laptop, workstation, net top etc.).

The external system memory 305 may be representative of any type of memory. For example, the external memory 305 may be in the DRAM family such as synchronous DRAM (SDRAM), double data rate (DDR, DDR2, DDR3, etc.), or any low power version thereof. However, external memory 305 may also be implemented in SDRAM, static RAM (SRAM), or other types of RAM, etc. Accordingly, external system memory 305 may also include the retention mode resistor described above in conjunction with the description of FIG. 2.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A memory comprising:
a storage array including a plurality of bit cells and a power rail configured to distribute an operating current to the plurality of bit cells;
a resistor coupled between a power supply and the power rail and configured to provide a path for current to the power rail from the power supply during operation in a retention mode; and
a switching device coupled between the power supply and the power rail and configured to convey operational current to the power rail from the power supply during operation in a normal mode.

2. The memory as recited in claim 1, wherein the switching device comprises a p-type transistor.

3. The memory as recited in claim 1, wherein the resistor comprises a polycrystalline silicon resistor formed in a semiconductor substrate within which the storage array is formed.

4. The memory as recited in claim 1, further comprising a control unit coupled to the switching device and configured to selectively generate a normal mode signal to enable and disable the switching device based upon received power mode information.

5. The memory as recited in claim 4, wherein the switching device is configured to convey current to the power rail in response to an active normal node signal.

6. The memory as recited in claim 4, wherein the control unit is configured to detect inactivity of the storage array and to responsively disable the switching device.

7. The memory as recited in claim 1, wherein in response to receiving power mode information that indicates a low power mode is being entered, the control unit is configured to disable the switching device.

8. A memory comprising:
a semiconductor substrate including:
a storage array including a plurality of bit cells and a power rail configured to distribute an operating current to the plurality of bit cells;
a resistor coupled between a power supply and the power rail, wherein the resistor is configured to provide a path for current to the power rail from the power supply during operation in a retention mode; and
a transistor coupled between the power supply and the power rail and configured to convey operational current to the power rail from the power supply during operation in a normal mode.

9. The memory as recited in claim 8, wherein the resistor is formed in a semiconductor substrate within which the storage array is formed.

10. The memory as recited in claim 8, wherein the transistor is configured to convey current to the power rail in response to an active normal node signal.

11. The memory as recited in claim 8, wherein the control unit is configured to detect inactivity of the storage array and to responsively disable the switching device.

12. The memory as recited in claim 8, wherein during operation in the retention mode, the current corresponds substantially to leakage current of the storage array.

13. A system comprising:
a memory; and
one or more processors coupled to the memory, wherein at least one of the one or more processors includes an embedded memory;
wherein the embedded memory includes:
a storage array including a plurality of bit cells and a power rail configured to distribute an operating current to the plurality of bit cells;
a resistor coupled between a power supply and the power rail and configured to provide a path for current to the power rail from the power supply during operation in a retention mode; and
a switching device coupled between the power supply and the power rail and configured to convey operational current to the power rail from the power supply during operation in a normal mode.

14. The system as recited in claim 13, wherein the embedded memory comprises a register file.

15. The system as recited in claim 13, wherein the embedded memory comprises a cache memory.

16. The system as recited in claim 13, wherein the resistor is a semiconductor material formed in a semiconductor substrate within which the storage array is formed.

17. A memory device comprising:
a power supply;
a storage array including a plurality of bit cells and a power rail configured to distribute an operating current to the plurality of bit cells, wherein the power rail is coupled to the power supply via a resistor in parallel with a switching device;
wherein during operation in a first mode, the switching device is configured to conduct operational current to the power rail, and during operation in a second mode the switching device blocks current, thereby allowing the resistor to provide a current path to the power rail.

18. The memory device as recited in claim 17, wherein the resistor is formed in a semiconductor substrate of the memory device.

19. The memory device as recited in claim 17, wherein the switching device is a p-type transistor.

20. A mobile communication device comprising:
a memory; and
a processor coupled to the memory, wherein the processor includes an embedded memory including:
a storage array including a plurality of bit cells and a power rail configured to distribute an operating current to the plurality of bit cells;
a resistor coupled between a power supply and the power rail and configured to provide a path for current to the power rail from the power supply during operation in a retention mode; and
a switching device coupled between the power supply and the power rail and configured to convey operational current to the power rail from the power supply during operation in a normal mode.

21. The mobile communication device as recited in claim 20, further comprising a control unit coupled to the switching device and configured to selectively generate a normal mode signal to enable and disable the switching device based upon received power mode information.

22. The mobile communication device as recited in claim 21, wherein the control unit is configured to detect inactivity of the storage array and to responsively disable the switching device.

23. The mobile communication device as recited in claim 21, wherein in response to receiving power mode information that indicates a low power mode is being entered, the control unit is configured to disable the switching device.

24. The mobile communication device as recited in claim 20, wherein the resistor is a semiconductor material formed in a semiconductor substrate within which the storage array is formed.
